(19) United States
(12) Patent Application Publication
(10) Pub. No.: US 2013/0307041 A1
(43) Pub. Date: Nov. 21, 2013

(54) METHOD OF MANUFACTURING DETECTION DEVICE, DETECTION DEVICE, AND DETECTION SYSTEM

(71) Applicant: CANON KABUSHIKI KAISHA, (US)

(72) Inventors: Chiori Mochizuki, Sagamihara-shi (JP); Minoru Watanabe, Honjo-shi (JP); Keigo Yokoyama, Honjo-shi (JP); Masato Ofuji, Honjo-shi (JP); Jun Kawanabe, Kodama-gun (JP); Kentaro Fujiyoshi, Tokyo (JP); Hiroshi Wayama, Saitama-shi (JP)

(73) Assignee: CANON KABUSHIKI KAISHA, Tokyo (JP)

(21) Appl. No.: 13/887,600

(22) Filed: May 6, 2013

(30) Foreign Application Priority Data
May 8, 2012 (JP) 2012-106883

(51) Int. Cl. H01L 27/146

(52) U.S. Cl. CPC H01L 27/14689; H01L 27/14643
USPC 257/292; 438/80

(57) ABSTRACT

Before transmitting a print job to a printing apparatus, a CPU of a print processing apparatus determines whether paper information designated in the print job has been registered in a paper information database of the print processing apparatus. If the paper information has not been registered, the CPU extracts paper information similar to the paper information designated in the print job from those stored in the paper information database of the print processing apparatus. Furthermore, the CPU copies information about the dependency on the printing apparatus, which is included in the extracted paper information (printer dependency information) to the paper information designated in the print job. Then, the CPU registers the paper information designated in the print job, to which the printer dependency information has been copied, in a paper information database of the printing apparatus and transmits the print job to the printing apparatus.

### BACKGROUND OF THE INVENTION

1. Field of the Invention

The present application relates to a method of manufacturing a detection device that is applied to, e.g., an image diagnosis apparatus for medical care, a nondestructive inspection apparatus, and an analysis apparatus using radiation. The present application further relates to the detection device and a detection system.

2. Description of the Related Art

Recently, the thin-film semiconductor manufacturing technology has been employed to manufacture a detection device including an array of pixels (pixel array), which is a combination of switch elements, e.g., thin-film transistors (TFTs), and conversion elements, e.g., photodiodes, for converting radiation or light to electric charges.

Each of pixels in related-art detection devices disclosed in Japanese Patent Laid-Open No. 2004-296654 and No. 2007-059887 includes a conversion element including a first electrode disposed on a substrate, a second electrode disposed above the first electrode, a semiconductor layer disposed between the first electrode and the second electrode, and an the impurity semiconductor layer disposed between the second electrode and the semiconductor layer. The first electrode, the second electrode, the semiconductor layer, and the impurity semiconductor layer are each separated per conversion element, and the second electrode is disposed on the inner side than a region where the impurity semiconductor layer is disposed.

In the structure disclosed in Japanese Patent Laid-Open No. 2004-296654 and No. 2007-059887, however, an uncovered region not covered with the second electrode exists in the impurity semiconductor layer, particularly, in the impurity semiconductor layer around the second electrode. Because the impurity semiconductor layer has much higher specific resistance than the second electrode, an electric field tends to be less efficiently applied to a region of the semiconductor layer, which contacts with the uncovered region of the impurity semiconductor layer, in comparison with the case where the second electrode is disposed over the entire impurity semiconductor layer. Even if an electric field is sufficiently applied to the relevant region of the semiconductor layer, when collecting electric charges generated in the relevant region of the semiconductor layer to the second electrode, a distance through which the electric charges generated in the relevant region of the semiconductor layer are moved in the impurity semiconductor layer is longer than a distance through which electric charges generated in a region of the semiconductor layer positioned just under the second electrode are moved. Therefore, a time required to collect the electric charges generated in the above-mentioned relevant region is prolonged and a collection speed of the electric charges is reduced. Thus, there is a possibility that response characteristics, e.g., sensitivity and an operation speed, of the detection device may degrade in comparison with those obtained in the case where the second electrode is disposed over the entire impurity semiconductor layer.

With the view of solving the above-described problems in the related art, the present invention provides a detection device that has good response characteristics as a result of suppressing reduction of the response characteristics.

### SUMMARY OF THE INVENTION

According to an embodiment of the present disclosure, there is provided a method of manufacturing a detection device including a plurality of conversion elements disposed on a substrate, each of the conversion elements including a first electrode disposed on the substrate, a second electrode disposed above the first electrode, a semiconductor layer disposed between the first electrode and the second electrode, and an impurity semiconductor layer disposed between the semiconductor layer and the second electrode, the method including a film forming step of successively forming, over the plural first electrodes, a semiconductor film becoming the semiconductor layer, an impurity semiconductor film becoming the impurity semiconductor layer, and an electroconductive film becoming the second electrode in mentioned order, a first removing step of partly removing the electroconductive film, thereby forming an electroconductive layer on each of the plural first electrodes, a second removing step of removing a part of the semiconductor film and a part of the impurity semiconductor film through spaces between the plural electroconductive layers by etching using an etchant having a reaction with the electroconductive film that is slower than a reaction with the impurity semiconductor film and a reaction with the semiconductor film, thereby forming the semiconductor layer and the impurity semiconductor layer on each of the plural first electrodes, and a third removing step of removing a part of the electroconductive layer, the part being positioned on an outer side of the conversion element than an end of the impurity semiconductor layer formed in the second removing step, thereby forming the second electrode.

With the embodiment as disclosed herein, the detection device for of suppressing reduction of the response characteristics and having good response characteristics can be provided.

Further features of the present invention will become apparent from the following description of exemplary embodiments with reference to the attached drawings.

### BRIEF DESCRIPTION OF THE DRAWINGS

FIG. 1A is a schematic plan view of one of pixels in a detection device according to a first embodiment, FIG. 1B is a schematic sectional view taken along a line IB-IB in FIG. 1A, and FIG. 1C is a schematic sectional view taken along a line IC-IC in FIG. 1A.

FIGS. 2A, 2C and 2E illustrate mask patterns to explain a method of manufacturing the detection device according to the first embodiment, and FIGS. 2B, 2D and 2F are schematic sectional views to explain the method of manufacturing the detection device according to the first embodiment.

FIG. 3A illustrates a mask pattern to explain the method of manufacturing the detection device according to the first embodiment, and FIGS. 3B, 3C and 3D are schematic sectional views to explain the method of manufacturing the detection device according to the first embodiment.

FIGS. 4A, 4D and 4G illustrate mask patterns to explain the method of manufacturing the detection device according to the first embodiment, and FIGS. 4B, 4C, 4E, 4F, 4H and 4I are schematic sectional views to explain the method of manufacturing the detection device according to the first embodiment.

FIG. 5 is a schematic equivalent circuit diagram of the detection device.

FIGS. 6A and 6B are schematic sectional views of one of pixels in a detection device according to a second embodiment.

FIGS. 7A, 7B and 7C are schematic sectional views to explain a method of manufacturing the detection device according to the second embodiment.

FIG. 8 is a conceptual illustration of a radiation detection system using the detection device according to the embodiment disclosed herein.

### DESCRIPTION OF THE EMBODIMENTS

Embodiments of the present invention will be described in detail below with reference to the accompanying drawings. It is to be noted that the term “radiation” used in this specification includes not only beams formed by particles (including photons) emitted through radioactive decay, such as an α-ray, a β-ray, and a γ-ray, but also beams having energy comparable to or more than the above-mentioned beams, such as an X-ray, a corpuscular ray, and a cosmic ray.

### First Embodiment

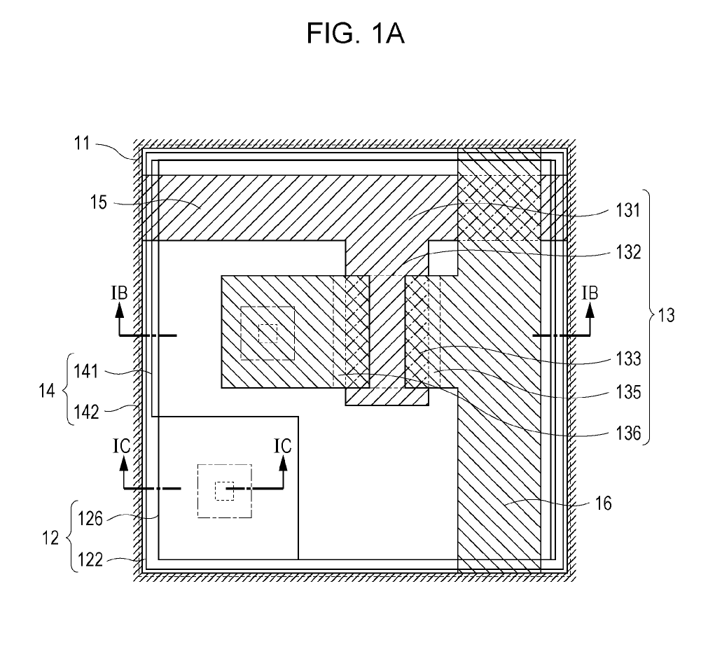

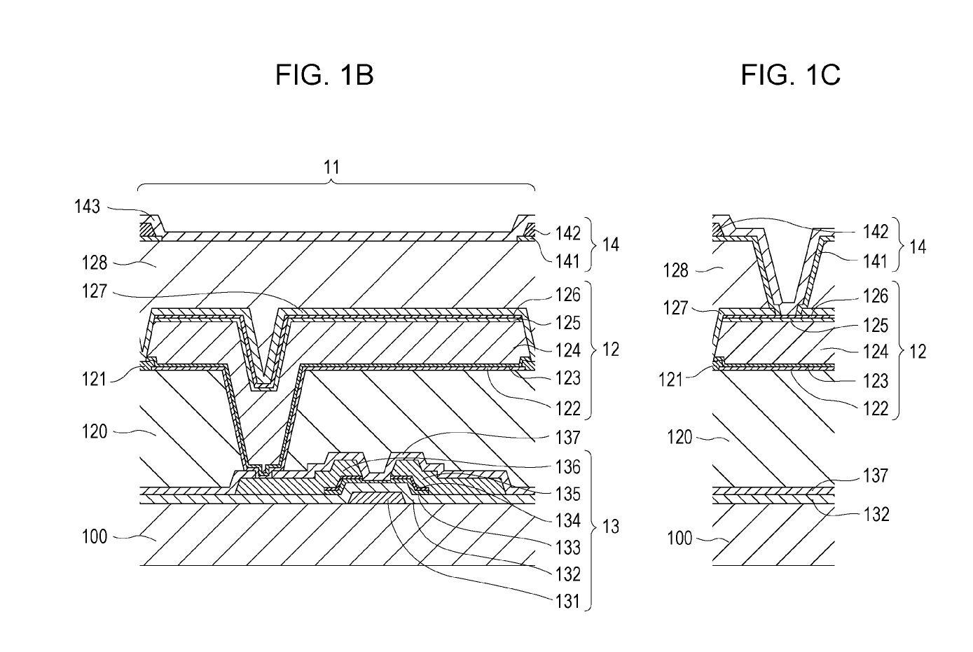

The structure of one pixel in a detection device according to a first embodiment of the present disclosure is first described with reference to FIG. 1A to 1C. FIG. 1A is a schematic plan view of one of the pixels. In FIG. 1A, insulating layers and a semiconductor layer of a conversion element are omitted for simplification of the drawing. FIG. 1B is a schematic sectional view taken along a line IB-IB in FIG. 1A, and FIG. 1C is a schematic sectional view taken along a line IB-IB in FIG. 1A. The insulating layers and the semiconductor layer of the conversion element, omitted in FIGS. 1A, are illustrated in FIGS. 1B and 1C.

One pixel 11 in the detection device according to the first embodiment of the present disclosure includes a conversion element 12 for converting radiation or light to electric charges, and a TFT (thin-film transistor) 13 serving as a switch element that transfers an electric signal corresponding to the electric charges converted by the conversion element 12. The conversion element 12 may be constituted as an indirect conversion element including a photoelectric conversion element and a wavelength converter for converting radiation to light in a wavelength band sensible by the photoelectric conversion element, or as a direct conversion element for directly converting radiation to electric charges. In this embodiment, a PIN photodiode made of primarily amorphous silicon is used as a photodiode that is one type of photoelectric conversion elements. The conversion element 12 is stacked above the TFT 113, which is disposed on an insulating substrate 100, e.g., a glass substrate, with a passivation layer 137 and a first interlayer insulating layer 120 interposed between the conversion element 12 and the TFT 113.

The TFT 13 includes a control electrode 131, a gate insulating layer 132, a semiconductor layer 133, an impurity semiconductor layer 134 having a higher impurity concentration than the semiconductor layer 133, a first main electrode 135, and a second main electrode 136, which are successively formed on the substrate 100 in the mentioned order from the substrate side. The control electrode 131 serves as a gate electrode of the TFT 13. The first main electrode 135 serves as one of a source electrode and a drain electrode of the TFT 13. The second main electrode 136 serves as the other of the source electrode and the drain electrode of the TFT 13. Partial regions of the impurity semiconductor layer 134 are contacted with the first main electrode 135 and the second main electrode 136, respectively. A region of the semiconductor layer 133, which is positioned between regions thereof contacting respectively with the above-mentioned partial regions of the impurity semiconductor layer 134, serves as a channel region of the TFT 13. The control electrode 131 is electrically connected to a control wiring 15. The first main electrode 135 is electrically connected to a signal wiring 16, and the second main electrode 136 is electrically connected to a first electrode 122 of the conversion element 12. In this embodiment, the first main electrode 135 and the signal wiring 16 are integrally constituted by the same electroconductive layer, and the first main electrode 135 is a part of the signal wiring 16. Furthermore, in this embodiment, the control electrode 131 and the control wiring 15 are integrally constituted by the same electroconductive layer, and the control electrode 131 is a part of the control wiring 15. The passivation layer 137 is made of an inorganic insulating material, e.g., silicon oxide or silicon nitride, and is disposed to cover the TFT 13, the control wiring 15, and the signal wiring 16. While, in this embodiment, an inverted-staggered TFT using the semiconductor layer 133 and the impurity semiconductor layer 134, each made of primarily amorphous silicon, is used as the switch element, the switch element used in the present invention is not limited to that type. As another example, a staggered TFT made of primarily polycrystalline silicon, an organic TFT, or an oxide TFT may also be used.

The first interlayer insulating layer 120 is disposed between the substrate 100 and the plural first electrodes 122 to cover the plural TFTs 13, and it has contact holes. The first electrode 122 of the conversion element 12 and the second main electrode 136 of the TFT 13 are electrically connected to each other in the contact hole formed in the first interlayer insulating layer 120. The first interlayer insulating layer 120 is advantageously made of an organic insulating material, which can be formed thick, to reduce a parasitic capacity between the conversion element 12 and each of the TFT 13, the control wiring 15, and the signal wiring 16.

The conversion element 12 includes the first electrode 122, an impurity semiconductor layer 123 of first conductivity type, a semiconductor layer 124, an impurity semiconductor layer 125 of second conductivity type, and the second electrode 126, which are successively formed on the first interlayer insulating layer 120 in the mentioned order from the first interlayer insulating layer side. Herein, the semiconductor layer 124 disposed between the first electrode 122 and the second electrode 126 is desirably an intrinsic semiconductor. The impurity semiconductor layer 123 of first conductivity type disposed between the first electrode 122 and the semiconductor layer 124 exhibits a polarity of first conductivity type, and it contains impurities of first conductivity type at a higher concentration than the semiconductor layer 124 and the impurity semiconductor layer 125 of second conductivity type. The impurity semiconductor layer 125 of second conductivity type disposed between the semiconductor layer 124 and the second electrode 126 exhibits a polarity of second conductivity type opposite to the first conductivity type, and it contains impurities of second conductivity type at a higher concentration than the impurity semiconductor layer 123 of first conductivity type and the semiconductor layer 124. The first conductivity type and the second conductivity type are conductivity types differing in polarity from each other. For example, when the first conductivity type is n-type, the second conductivity type is p-type. An electrode wiring 14 (described later) is electrically connected to the second electrode 126 of the conversion element 12. The first electrode 122 of the conversion element 12 is electrically connected to the second main electrode 136 of the TFT 13 in the contact hole formed in the first interlayer insulating layer 120. While this embodiment employs the photodiode including the impurity semiconductor layer 123 of first conductivity type, the semiconductor layer 124, and the impurity semiconductor layer 125 of second conductivity type, those layers being made of primarily amorphous silicon, the photodiode usable in the present application is not limited to that type. As another example, an element of directly converting radiation to electric charges may also be used. Such an element may include the impurity semiconductor layer 123 of first conductivity type, the semiconductor layer 124, and the impurity semiconductor layer 125 of second conductivity type, those layers being made of primarily amorphous selenium. The first electrode 122 and the second electrode 126 of the conversion element 12 are each made of a transparent electroconductive oxide, e.g., light-transmissive ITO. However, the first electrode 122 may be made of a metallic material. In particular, when the conversion element 12 is an indirect conversion element including a photoelectric conversion element and a wavelength converter, the transparent electroconductive oxide, e.g., light-transmissive ITO, is used for the second electrode 126 that is an electrode positioned on the wavelength converter side. On the other hand, the first electrode 122 positioned farther away from the wavelength converter than the second electrode 126 may be made of an electrical conductor made of Al and having low light transmissivity. In this embodiment of the present disclosure, the impurity semiconductor layer 125 of second conductivity type and the second electrode 126 are disposed such that an end of the impurity semiconductor layer 125 of second conductivity type and an end of the second electrode 126 are positioned on a linear line in a direction perpendicular to their surfaces.

Between adjacent two of the plural first electrodes 122 on the first interlayer insulating layer 120, an insulating member (layer) 121 made of an inorganic insulating material is disposed in contact with the first interlayer insulating layer 120. Thus, the first electrode 122 and the insulating member 121 are disposed on the first interlayer insulating layer 120 to cover the first interlayer insulating layer 120. Accordingly, when an impurity semiconductor film becoming the impurity semiconductor layer 123 is formed, the surface of the first interlayer insulating layer 120 is not exposed and mixing of an organic insulating material into the impurity semiconductor layer 123 can be reduced. Moreover, in this embodiment, the impurity semiconductor layer 123, the semiconductor layer 124, and the impurity semiconductor layer 125 are separated for each pixel above the insulating member 121. In a dry etching step for that separation, since the insulating member 121 serves as an etching stop layer, the first interlayer insulating layer 120 is avoided from being exposed to species used in the dry etching, and the surrounding layers can be prevented from being contaminated by the organic insulating material.

The passivation layer 127 and a second interlayer insulating layer 128 are disposed to cover the conversion element 12. The passivation layer 127 is made of an inorganic insulating material, e.g., silicon oxide or silicon nitride, and it covers the conversion element 12 and the insulating member 121. The second interlayer insulating layer 128 is disposed between the second electrode 126 and the electrode wiring 14 to cover the passivation layer 127. The passivation layer 127 and the second interlayer insulating layer 128 have contact holes. The second electrode 126 of the conversion element 12 and the electrode wiring 14 are electrically connected to each other in the contact holes formed in the passivation layer 127 and the second interlayer insulating layer 128. The second interlayer insulating layer 128 is advantageously made of an organic insulating material, which can be formed thick, to reduce a parasitic capacity between the conversion element 12 and the electrode wiring 14.

The electrode wiring 14 includes a first electroconductive layer 141 made of a transparent electroconductive oxide and disposed on the second interlayer insulating layer 128, and a second electroconductive layer 142 made of a metallic material and disposed on the first electroconductive layer 141. The first electroconductive layer 141 is connected to the second electrode 126 of the conversion element 12 in the contact holes formed in the passivation layer 127 and the second interlayer insulating layer 128. The second electroconductive layer 142 is disposed on the first electroconductive layer 141 such that an orthographic projection of the second electroconductive layer 142 is positioned between the two first electrodes 122 of the two conversion elements 12 adjacent to each other.

A passivation layer 143 made of an inorganic insulating material, e.g., silicon oxide or silicon nitride, is disposed to cover the electrode wiring 14.

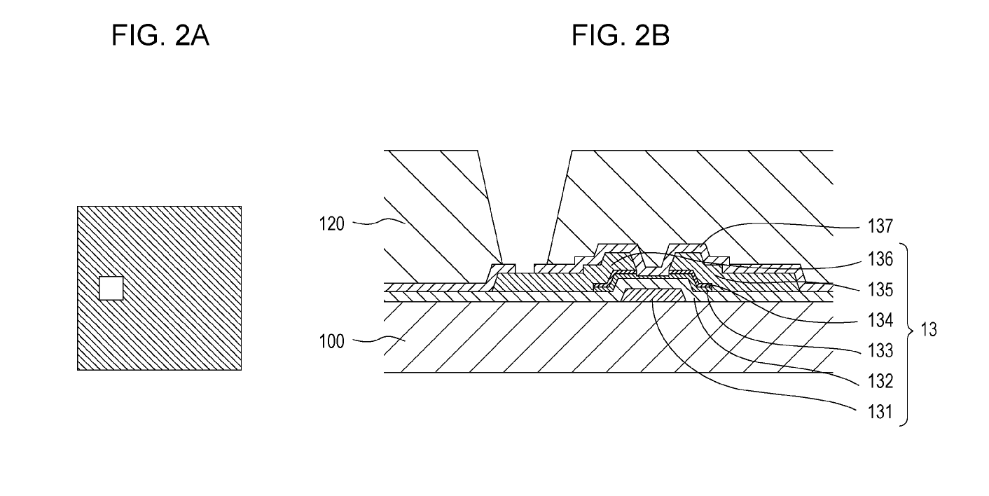

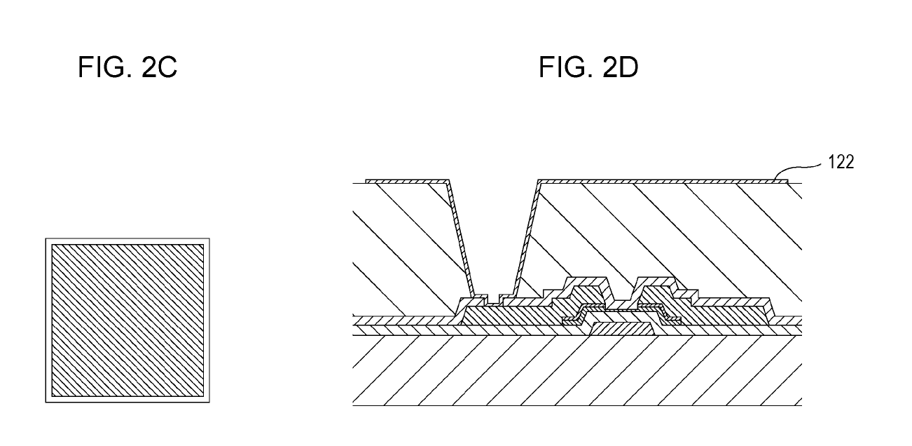

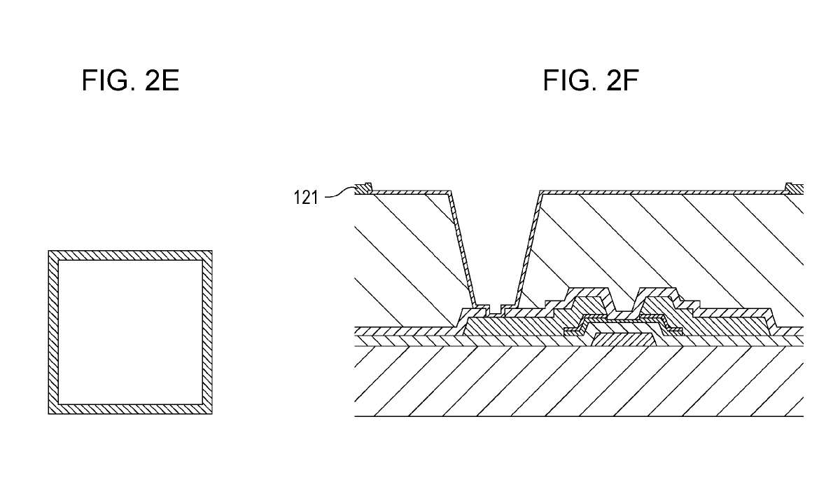

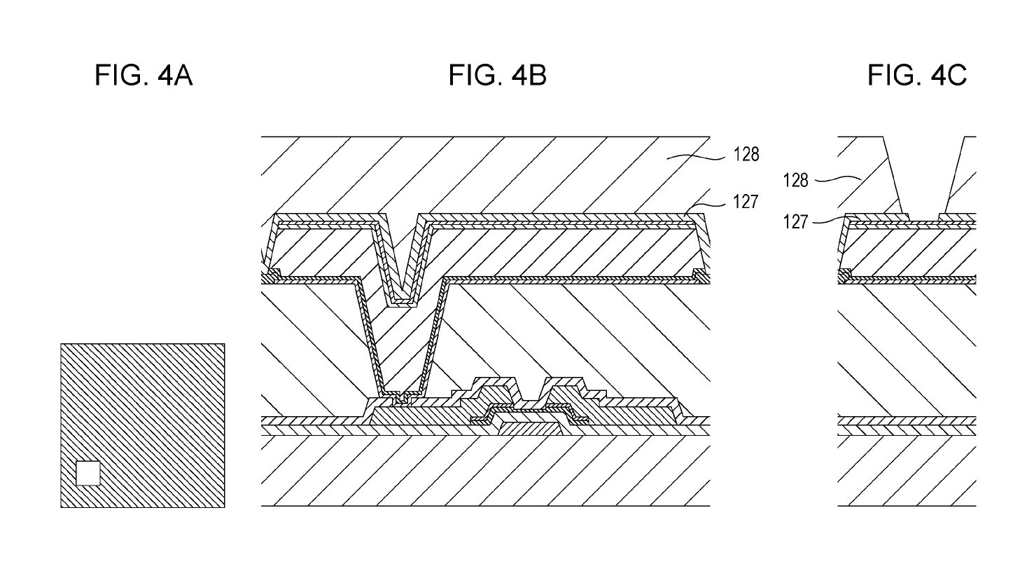

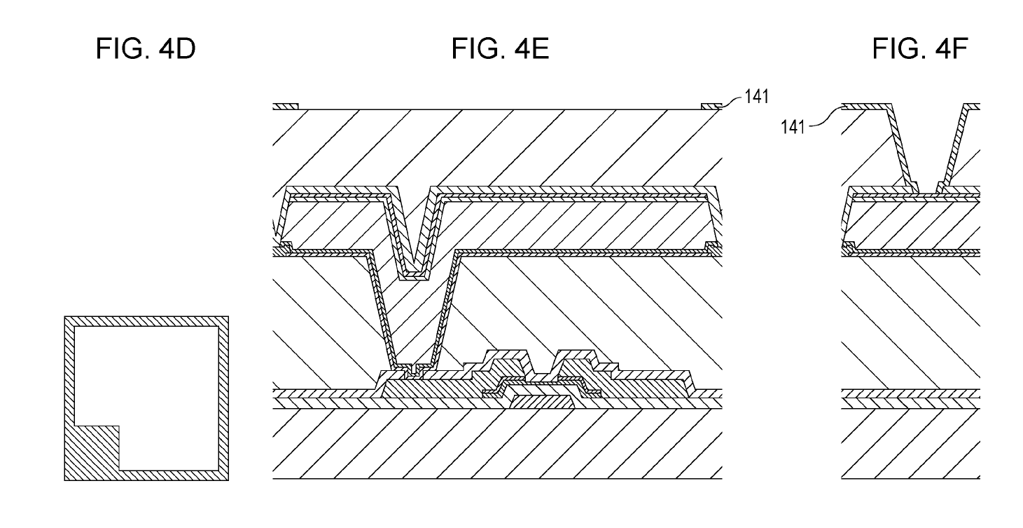

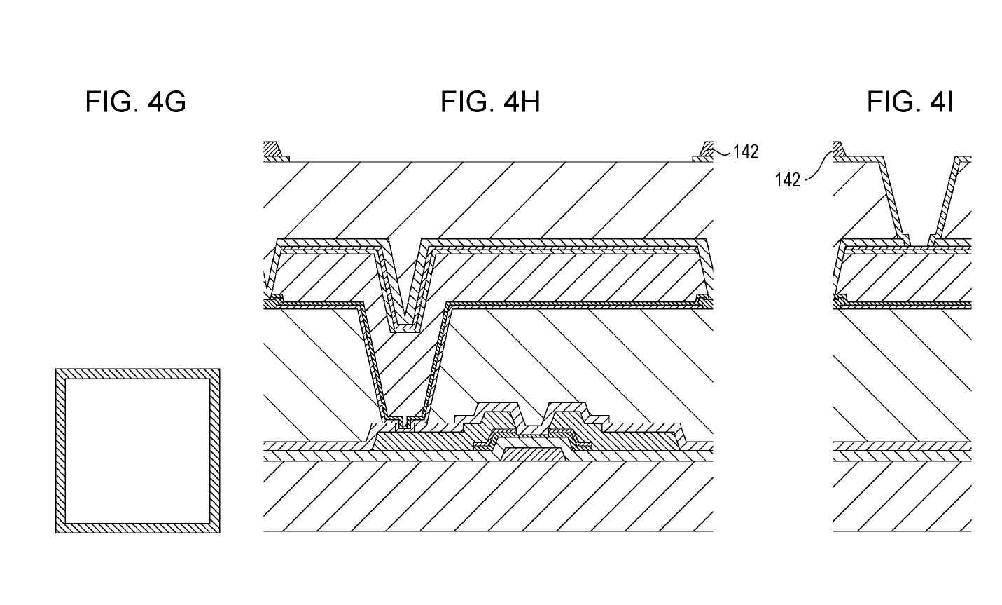

A method of manufacturing the detection device according to the first embodiment of the present disclosure will be described below with reference to FIGS. 2A to 41. In particular, a process subsequent to a step of forming the contact hole in the first interlayer insulating layer 120 is described in detail with reference to mask patterns and sectional views during the process. FIGS. 2A, 2C and 2E, FIG. 3A, and FIGS. 4A, 4D and 4G are schematic plan views of the mask patterns for photomasks (masks) used in relevant steps. FIGS. 2B, 2D and 2F, FIGS. 3B, 3C and 3D, and FIGS. 4B, 4E and 4H are schematic sectional views in relevant steps, each taken along a line corresponding to the line IB-IB in FIG. 1A. FIGS. 4C, 4F and 4I are schematic sectional views in relevant steps, each taken along a line corresponding to the line IC-IC in FIG. 1A.

The plural TFTs 13 are disposed on the insulating substrate 100, and a protective layer 137 is disposed to cover the plural TFTs 13. A contact hole is formed by etching in the protective layer 137 in its portion on the second main electrode 136 where the second main electrode 136 is electrically connected to the photodiode. In a step illustrated in FIG. 2B, an acrylic resin, i.e., an organic insulating material having photosensitivity, is formed as an interlayer insulating film to cover the TFTs 13 and the protective layer 137 by employing a coating device, e.g., a spinner. A polyimide resin or the like is also usable as the organic insulating material having photosensitivity. The first interlayer insulating layer 120 having the contact hole above the second main electrode 136 is then formed through an exposure and development process with the use of the mask illustrated in FIG. 2A.

In a step illustrated in FIG. 2D, an electroconductive film, e.g., an amorphous transparent electroconductive oxide film made of ITO, is formed by sputtering to cover the second main electrode 136 and the first interlayer insulating layer 120. Then, the first electrode 122 of the conversion element 12 is formed by removing a part of the transparent electroconductive oxide film by wet etching using the mask illustrated in FIG. 2C, and polycrystallizing the transparent electroconductive oxide film by annealing.

In a step illustrated in FIG. 2F, an insulating film made of an inorganic insulating material, e.g., a film of silicon nitride, is formed by plasma CVD to cover the first interlayer insulating layer 120 and the first electrode 122. Then, the insulating member 121 is formed between the pixels by etching the above-mentioned insulating film with the use of the mask illustrated in FIG. 2E. As a result, the surface of the first interlayer insulating layer 120 is covered with the insulating member 121 and the first electrode 122.

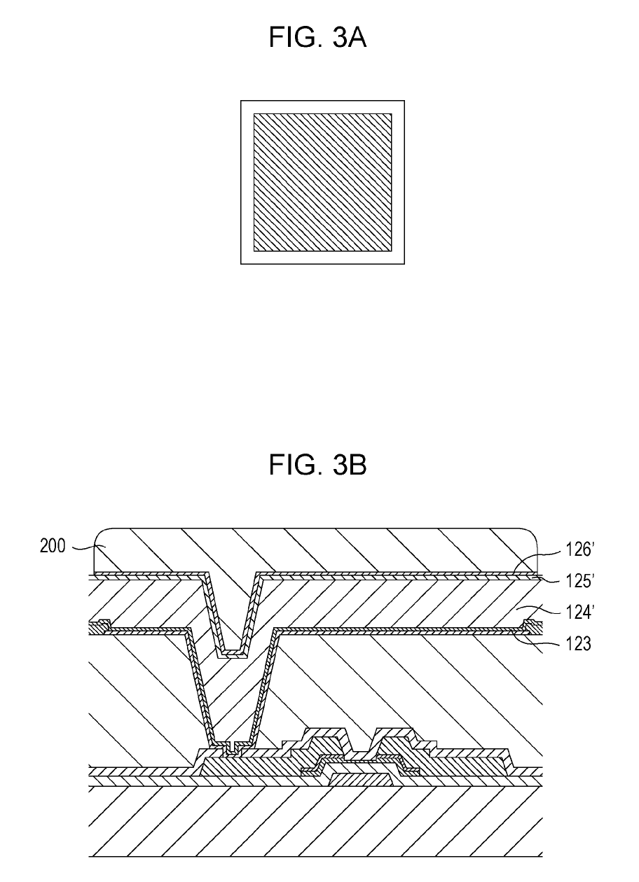

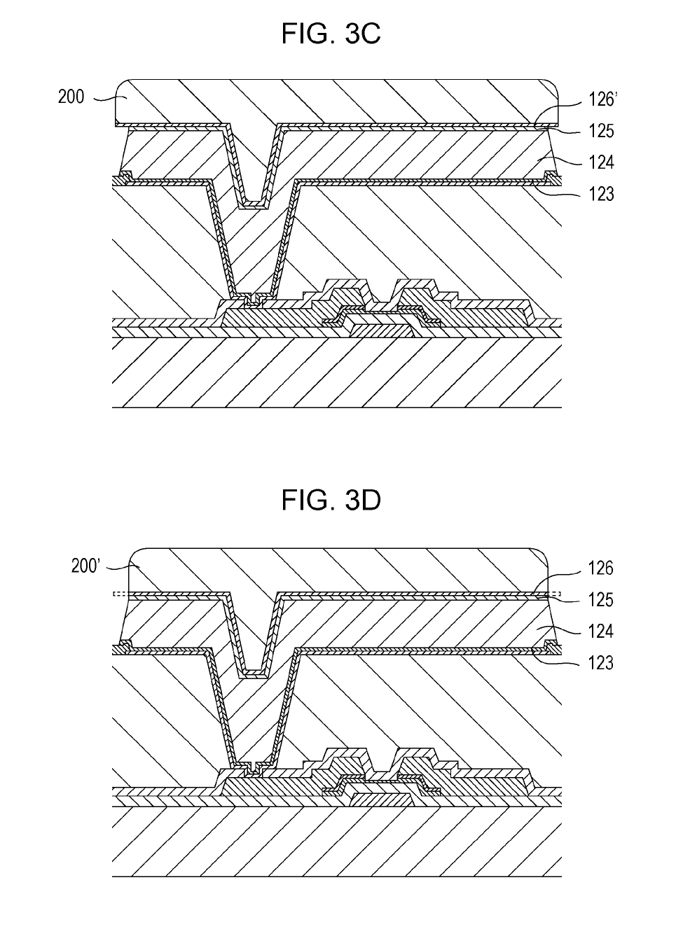

In a step illustrated in FIG. 3B, an amorphous silicon film containing a pentavalent element, e.g., phosphorous, mixed therein as an impurity is formed as an impurity semiconductor film 123′ of first conductivity type by plasma CVD to cover the insulating member 121 and the first electrode 122. Then, a semiconductor film 124′ made of an amorphous silicon film and an amorphous silicon film containing a trivalent element, e.g., boron, mixed therein as an impurity and serving as an impurity semiconductor film 125′ of second conductivity type are successively formed in the mentioned order by plasma CVD. An electroconductive film, e.g., a transparent electroconductive oxide film, is then formed by sputtering to cover the impurity semiconductor film 125′ of second conductivity type. A series of the step of forming the impurity semiconductor film 123 of first conductivity type to the step of forming the electroconductive film, described above, is called a film forming step.

A resist 200 is formed on the transparent electroconductive oxide film with the use of the mask illustrated in FIG. 3A, and the transparent electroconductive oxide film is partly removed by wet etching using the resist 200, thereby forming an electroconductive layer 126′. For example, a mixed solution of hydrochloric acid and nitric acid can be used as an etchant in the wet etching of the transparent electroconductive oxide film. When dry-etching the transparent electroconductive oxide film, a hydrogen iodide gas, for example, can be used as an etchant. The above-mentioned step is called a first removing step.

In a step illustrated in FIG. 3C, the impurity semiconductor film 125′ of second conductivity type, the semiconductor film 124′, and the impurity semiconductor film 123′ of first conductivity type are each partly removed by dry etching through spaces between the plural electroconductive layers 126′ with the use of the resist 200 that is left without being removed. With the above dry etching, an array of conversion elements 12 is separated for each pixel. As a result, the impurity semiconductor layer 125, the semiconductor layer 124, the impurity semiconductor layer 123, and the electroconductive layer 126′ are successively formed on each of the plural first electrodes 122. Herein, the impurity semiconductor layer 125 is obtained by partly removing the impurity semiconductor film 125′, the semiconductor layer 124 is obtained by partly removing the impurity semiconductor film 124′, and the impurity semiconductor layer 123 is obtained by partly removing the impurity semiconductor film 123′. The electroconductive layer 126′ is obtained by partly removing the above-mentioned electroconductive film. Such a step is called a second removing step. The above-described element separation by the dry etching is effectuated on the insulating member 121. Accordingly, the insulating member 121 functions as an etching stop layer, whereby the first interlayer insulating layer 120 is avoided from being exposed to species used in the dry etching and the surrounding layers can be prevented from being contaminated by the organic insulating material. A gas mixture of fluorine gas and chloride gas is used as an etchant for the dry etching. This enables the impurity semiconductor film 123′ of first conductivity type, etc. and the insulating member 121 to be etched at a high selectivity. The reaction of the electroconductive layer 126′ with respect to such an etchant for the dry etching is much slower than that of the silicon-based films, and the electroconductive layer 126′ is removed at a lower rate than the silicon-based films. While the silicon-based films are removed by the dry etching in this embodiment, the present application is not limited to the use of dry etching. For example, wet etching using an etchant, prepared by diluting hydrofluoric-nitric acid, i.e., a mixture of hydrofluoric acid and nitric acid, with acetic acid may be used instead. In that case, too, the reaction of the electroconductive layer 126′ with respect to such an etchant for the wet etching is much slower than that of the silicon-based films, and the electroconductive layer 126′ is removed at a lower rate than the silicon-based films. However, it is more advantageous to use the dry etching because the dry etching exhibits higher anisotropy than the wet etching. Even in the case using the dry etching, the respective ends of the impurity semiconductor layer 125 and the semiconductor layer 124 are retracted from the end of the resist 200 such that the end of the impurity semiconductor layer 125 is positioned on the inner side than the end of the electroconductive layer 126′. If such a structure remains, there is a risk that the respective ends of the impurity semiconductor layer 125 and the semiconductor layer 124 may not be covered with the passivation layer 127, formed later, in some areas, and that durability against intrusion of impurities and moisture into the conversion element 12 may deteriorate. One conceivable solution to avoid the end of the impurity semiconductor layer 125 from being positioned on the inner side of the conversion element 12 than the end of the electroconductive layer 126′ is to form the second electrode 126 and the impurity semiconductor layer 125 by employing different masks. In consideration of a mask alignment margin, however, an end of a resist formed with the mask used in forming the second electrode 126 has to be set on the inner side than an end of a resist formed with the mask used in forming the impurity semiconductor layer 125. Such setting results in a structure similar to that in Japanese Patent Laid-Open No. 2004-296654 and No. 2007-059887.

In view of the above-mentioned problem, in a step illustrated in FIG. 3D, an ashing process is performed on the resist 200, which has been used in the step illustrated in FIG. 3B, to remove only a part of the resist 200 such that the end of the resist 200 is aligned with the end of the impurity semiconductor layer 125, thereby forming a resist 200′. The ashing process is to remove the resist by ashing the same with ozone or plasma in gas phase. In the ashing process, an amount by which the resist is removed (i.e., a distance by which the end of the resist is retracted) can be preset depending on conditions. Furthermore, a distance by which the end of the impurity semiconductor layer 125 is retracted can also be preset depending on respective materials and thicknesses of the impurity semiconductor layer 125, the semiconductor layer 124, and the impurity semiconductor layer 123, the type of the etchant, the processing time, and the processing temperature. Thus, the end of the resist 200 is retracted by the ashing where ashing conditions are set to be adapted for the distance by which the end of the impurity semiconductor layer 125 is retracted. Herein, the ashing conditions for setting the amount by which the resist is removed to be matched with the distance by which the end of the impurity semiconductor layer 125 is retracted are typically the ashing temperature and/or the ashing time. When ozone ashing is employed, an ozone concentration is further included in the ashing conditions in addition to the above-mentioned parameters. When plasma ashing is employed, various conditions for producing plasma are further included in the ashing conditions in addition to the above-mentioned parameters. With the proper setting of the ashing conditions, the resist 200′ can be formed such that the end of the resist 200′ and the end of the impurity semiconductor layer 125 are positioned on one linear line extending in a direction perpendicular to the surface of the impurity semiconductor layer 125. The second electrode 126 is then formed by removing a part of the electroconductive layer 126′, which part is positioned on the outer side of the conversion element 12 than the end of the impurity semiconductor layer 125, by the wet etching again with the use of the resist 200′. By forming the second electrode 126 through two steps of the wet etching as described above, the end of the second electrode 126 can be formed in alignment with the end of the impurity semiconductor layer 125. Stated in another way, the second electrode 126 can be formed such that the end of the impurity semiconductor layer 125 and the end of the second electrode 126 are positioned on one linear line extending in the direction perpendicular to the surfaces of the impurity semiconductor layer 125 and the second electrode 126. While this embodiment has been described as employing the step of forming the end of the second electrode 126 by the wet etching, the present disclosure is not limited to such a process. As another example, the step of forming the end of the second electrode 126 may be performed by dry etching using a hydrogen iodide gas as an etchant. It is to be noted that the step of forming the end of the second electrode 126 by etching-away is called a third removing step.

In consideration of a process margin, however, it is not easy to align the end of the impurity semiconductor layer 125 and the end of the second electrode 126 with each other, and both the ends may slightly shift in some cases. In such a case, the end of the second electrode 126 formed by the third removing step is more advantageously positioned on the inner side of the conversion element 12 relative to the end of the impurity semiconductor layer 125 than being positioned on the outer side thereof. Additionally, a mutual shift between both the ends is allowed when the following formula is satisfied;

4×Rs(D/P)≦Ron

where a distance between the end of the second electrode 126 and the end of the impurity semiconductor layer 125 is D (μm), a width of the conversion element 12 is P (μm), sheet resistance of the impurity semiconductor layer 125 is Rs (Ω), and on-resistance of the TFT 13 is Ron (Ω).

While this embodiment has been described in connection with the method of etching the electroconductive film, the impurity semiconductor layer 125, etc. without removing the resist 200, the present disclosure is not limited to that method. An alternative method is, for example, as follows. The resist 200 is removed after the step illustrated in FIG. 3B, and the impurity semiconductor layer 125′, etc. are etched by dry etching using a gas mixture of fluorine gas and chloride gas. Then, the resist 200 is formed again as illustrated in FIG. 3B, and the step illustrated in FIG. 3C is performed. In consideration of a process margin at the time of forming the resist 200 again, however, it is more advantageous to perform the above-described etching without removing the resist 200.

In a step illustrated in FIGS. 4B and 4C, an insulating film made of an inorganic insulating material, e.g., silicon nitride is formed by plasma CVD to cover the conversion element 12 and the insulating member 121. Then, an acrylic resin, i.e., an organic insulating material having photosensitivity, is formed as an interlayer insulating layer to cover the insulating film. The second interlayer insulating layer 128 and the passivation layer 127 having contact holes above the second electrode 126, as illustrated in FIG. 4C, are formed with the use of the mask illustrated in FIG. 4A.

In a step illustrated in FIGS. 4E and 4F, a transparent electroconductive oxide film is formed by sputtering to cover the second interlayer insulating layer 128 and the second electrode 126. Then, the first electroconductive layer 141 is formed by wet-etching the transparent electroconductive oxide film with the use of the mask illustrated in FIG. 4D.

In a step illustrated in FIGS. 4H and 4I, a metal film made of, e.g., Al is formed by sputtering to cover the first electroconductive layer 141 and the second interlayer insulating layer 128. Then, the second electroconductive layer 142 is formed on a part of the first electroconductive layer 141 by wet-etching the metal film with the use of the mask illustrated in FIG. 4G. With the above-mentioned step, the second electroconductive layer 142 and the second electrode 126 of the conversion element 12 are electrically connected to each other through the first electroconductive layer 141. At that time, reduction of an aperture ratio can be suppressed by forming the first electroconductive layer 141 using a transparent electroconductive oxide. Thus, as illustrated in FIGS. 4H and 4I, the electrode wiring 14 made up of the first electroconductive layer 141 and the second electroconductive layer 142 is formed. The structures illustrated in FIGS. 1B and 1C are then obtained by forming the passivation layer 143 to cover the electrode wiring 14 and the second interlayer insulating layer 128.

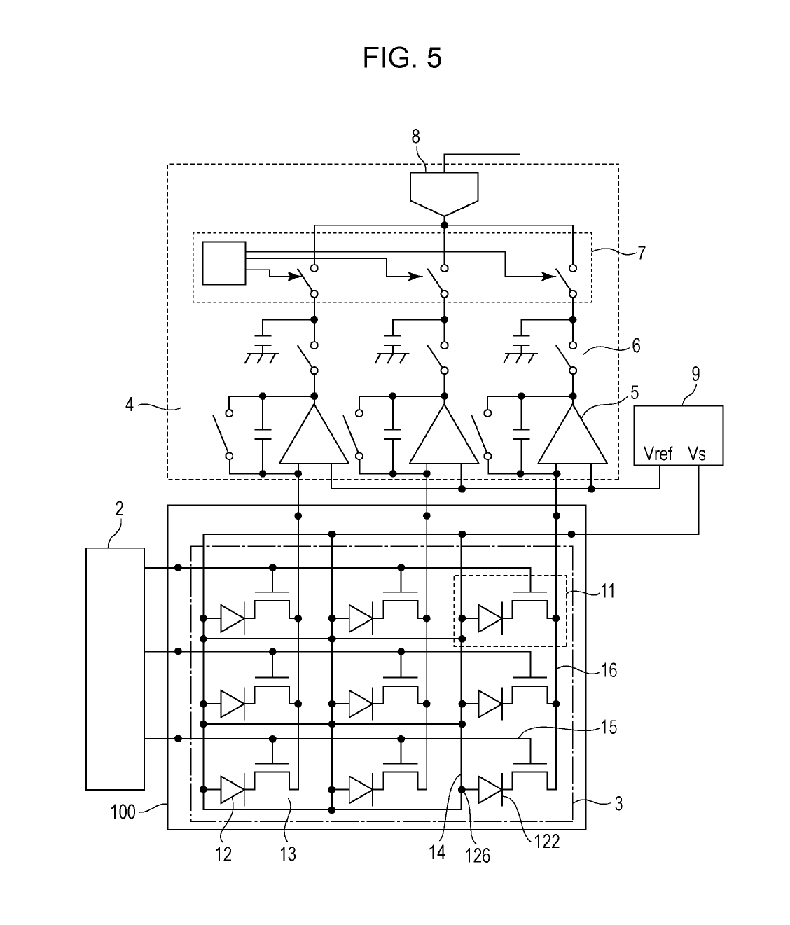

An equivalent circuit of the detection device according to the first embodiment of the present application will be described below with reference to FIG. 5. While FIG. 5 illustrates an equivalent circuit diagram of 3 rows×3 columns for simplification of the description, the present disclosure is not limited to such a configuration. The detection device includes a pixel array of n rows×m columns (n and m are each a natural number equal to or more than 2). In the detection device according to this embodiment, a conversion section 3 including a plurality of pixels 11 arrayed in each of a row direction and a column direction is disposed on the surface of the substrate 100. Each pixel 11 includes the conversion element 12 for converting radiation or light to electric charges, and the TFT 13 for outputting an electric signal corresponding to the electric charges generated by the conversion element 12. In this embodiment, since a PIN photodiode is used as the conversion element 12, a scintillator (not illustrated) for wavelength conversion from radiation to visible light may be disposed on the surface of the conversion element 12 on the side closer to the second electrode 126. The electrode wiring 14 is connected in common to the second electrodes 126 of the plural conversion elements 12. The control wiring 15 is connected in common to the control electrodes 131 of the plural TFTs 13 arrayed in the row direction, and is electrically connected to a drive circuit 2. With the drive circuit 2 successively or simultaneously supplying drive pulses to the plural control wirings 15 arrayed in the column direction, electric signals from the pixels are output in parallel in units of row to the plural signal wirings 16 that are arrayed in the column direction. Each signal wiring 16 is connected in common to the first main electrodes 135 of the plural TFTs 13 arrayed in the column direction, and is electrically connected to a read circuit 4. The read circuit 4 includes, per the signal wiring 16, an integral amplifier 5 for integrating and amplifying the electric signal from the signal wiring 16, and a sample and hold circuit 6 for sampling and holding the electric signal amplified by and output from the integral amplifier 5. The read circuit 4 further includes a multiplexer 7 for converting the electric signals, which are output in parallel from the plural sample and hold circuits 6, to serial electric signals, and an A/D converter 8 for converting the output electric signals to digital data. A reference potential Vref from a power supply circuit 9 is supplied to a non-inverted input terminal of the integral amplifier 5. Furthermore, the power supply circuit 9 is electrically connected to the electrode wirings 14 arrayed in a grid pattern, and it supplies a bias potential Vs to the second electrode 126 of each conversion element 12.

The operation of the detection device according to this embodiment will be described below. The reference potential Vref is applied to the first electrode 122 of the conversion element 12 through the TFT 13, and the bias potential Vs necessary for separating an electron-hole pair, generated by radiation or visible light, is applied to the second electrode 126. In such a state, the radiation having transmitted through a subject or the visible light corresponding to that radiation enters the conversion element 12 and is converted to electric charges, which are accumulated in the conversion element 12. An electric signal corresponding to the electric charges are output to the signal wiring 16 upon the TFF 13 being brought into a conducted state with a drive pulse applied to the control wiring 15 from the drive circuit 2. The electric signal is then read out as digital data to the exterior by the read circuit 4.

### Second Embodiment

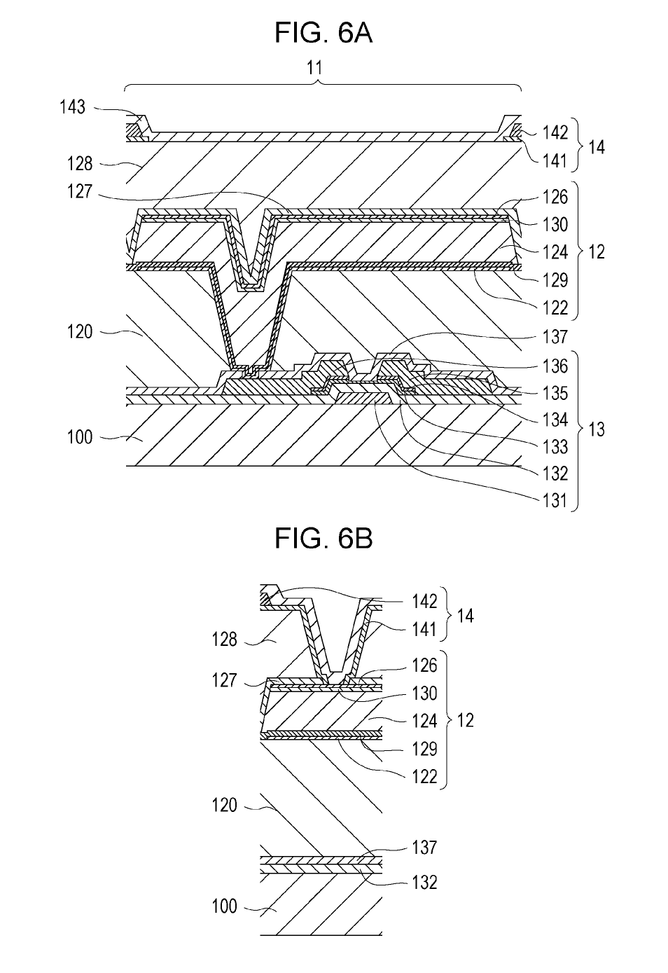

The structure of one pixel in a detection device according to a second embodiment of the present disclosure will be described below with reference to FIG. 6A and 6B. FIG. 6A is a schematic sectional view taken along a line corresponding to the line IB-IB in FIG. 1A, and FIG. 6B is a schematic sectional view taken along a line corresponding to the line IC-IC in FIG. 1A.

In the second embodiment, an MIS photoelectric conversion element is used as the conversion element 12 instead of the PIN photodiode used in the first embodiment. In more detail, the conversion element 12 includes a first electrode 122, an insulating layer 129, a semiconductor layer 124, an impurity semiconductor layer 130 of first conductivity type, and a second electrode 126, which are successively formed on the first interlayer insulating layer 120 in the mentioned order from the first interlayer insulating layer side. Herein, the insulating layer 129 disposed between the first electrode 122 and the semiconductor layer 124 is not separated per the conversion element 12 and is disposed to extend over the plural conversion elements 12. Therefore, the insulating member 121 in the first embodiment is not used in the second embodiment.

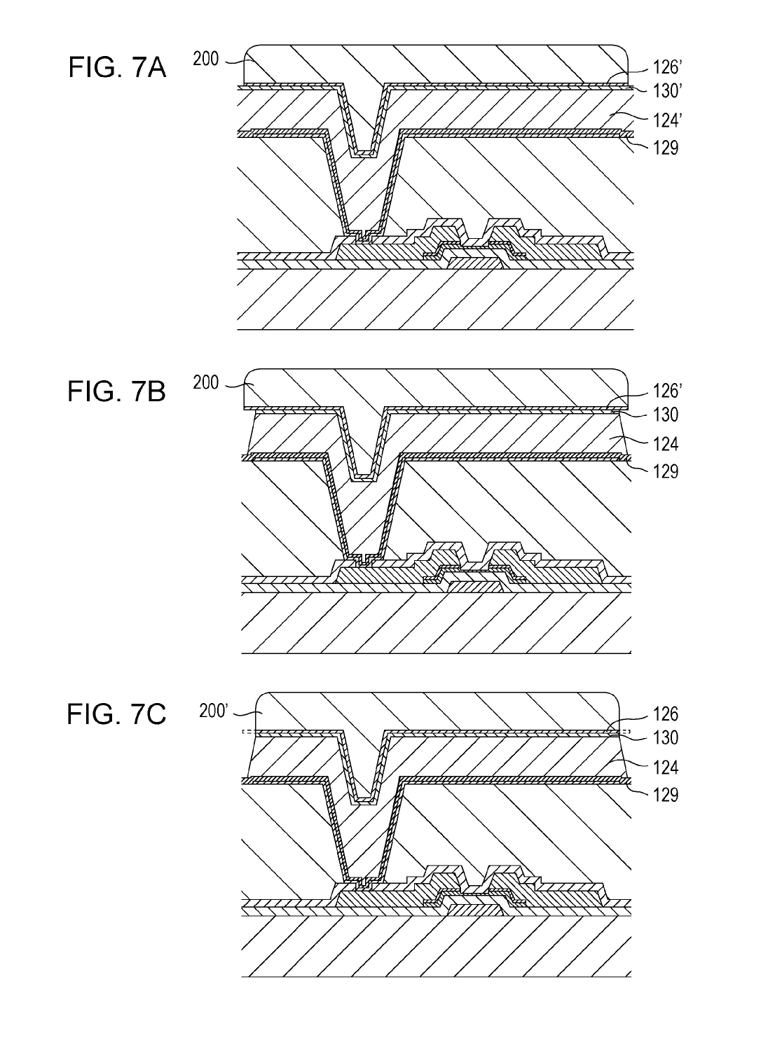

A method of manufacturing the detection device according to the second embodiment will be described below with reference to FIGS. 7A, 7B and 7C. Description of the same steps as those in the first embodiment is omitted here. More specifically, the steps illustrated in FIGS. 2B, 2D and FIGS. 4B, 4C, 4E, 4F, 4H and 4I are in common to the first embodiment and the second embodiment.

In a step illustrated in FIG. 7A subsequent to the step illustrated in FIG. 2D, the insulating layer 129 made of a silicon nitride film is formed by plasma CVD to cover the first interlayer insulating layer 120 and the first electrode 122. Then, a semiconductor film 124′ made of an amorphous silicon film and an amorphous silicon film containing a pentavalent element, e.g., phosphorus, mixed therein as an impurity and serving as an impurity semiconductor film 130′ of first conductivity type are successively formed in the mentioned order by plasma CVD. An electroconductive film, e.g., a transparent electroconductive oxide film, is then formed by sputtering to cover the impurity semiconductor film 130′ of first conductivity type. A series of the step of forming the insulating layer to the step of forming the electroconductive film, described above, also corresponds to the above-mentioned film forming step. Then, a resist 200 is formed with the use of the mask illustrated in FIG. 3A, and the transparent electroconductive oxide film is partly removed by wet etching using a similar etchant to that used in the first embodiment, thus forming an electroconductive layer 126′. Such a step also corresponds to the first removing step.

In a step illustrated in FIG. 7B, the impurity semiconductor film 130′ of first conductivity type and the semiconductor film 124′ are each partly removed by dry etching through spaces between the plural electroconductive layers 126′ with the use of the resist 200 that is left without being removed. With the above dry etching, an array of conversion elements 12 is separated for each pixel. Thus, the semiconductor layer 124 and the impurity semiconductor layer 130 are formed in the separated conversion element 12.

At that time, the insulating layer 129 is not entirely removed, and a part of the insulating layer 129 remains as it is. As a result, the semiconductor layer 124, the impurity semiconductor layer 130, and the electroconductive layer 126′ are formed on each of the plural first electrodes 122. Herein, the impurity semiconductor layer 130 is obtained by partly removing the impurity semiconductor film 130′. Such a step also corresponds to the second removing step. The above-described pixel separation by the dry etching is effectuated on the insulating layer 129. Accordingly, the insulating layer 129 functions as an etching stop layer, whereby the first interlayer insulating layer 120 is avoided from being exposed to species used in the dry etching and the surrounding layers can be prevented from being contaminated by the organic insulating material. A similar etchant to that used in the first embodiment is also used for the dry etching in the second embodiment. With the dry etching, as described above, the respective ends of the impurity semiconductor layer 130 and the semiconductor layer 124 are retracted from the end of the resist 200 such that the end of the impurity semiconductor layer 130 is positioned on the inner side than the end of the electroconductive layer 126′.

In a step illustrated in FIG. 7C, an ashing process is performed on the resist 200, which has been used in the step illustrated in FIG. 7A, to remove only a part of the resist 200 such that the end of the resist 200 is aligned with the end of the impurity semiconductor layer 130, thereby forming a resist 200′. In the ashing process, a distance by which the end of the resist is retracted can be preset depending on respective materials and thicknesses of the impurity semiconductor layer 130 and the semiconductor layer 124, the type of the etchant, the processing time, and the processing temperature. Thus, as in the first embodiment, the end of the resist 200 is retracted by the ashing where ashing conditions are set to be adapted for the distance by which the end of the impurity semiconductor layer 130 is retracted. With the proper setting of the ashing conditions, the resist 200′ can be formed such that the end of the resist 200′ and the end of the impurity semiconductor layer 130 are positioned on one linear line extending in a direction perpendicular to the surface of the impurity semiconductor layer 130. The second electrode 126 is then formed by removing a part of the electroconductive layer 126′ by the wet etching again with the use of the resist 200′. By forming the second electrode 126 through two steps of the wet etching as described above, the end of the second electrode 126 can be formed in alignment with the end of the impurity semiconductor layer 130. Stated in another way, the second electrode 126 can be formed such that the end of the impurity semiconductor layer 130 and the end of the second electrode 126 are positioned on one linear line extending in the direction perpendicular to the surfaces of the impurity semiconductor layer 130 and the second electrode 126. The above-mentioned step also corresponds to the third removing step. In consideration of a process margin, however, it is not easy to align the end of the impurity semiconductor layer 130 and the end of the second electrode 126 with each other, and both the ends may slightly shift in some cases. In such a case, the end of the second electrode 126 formed by the third removing step is more advantageously positioned on the inner side of the conversion element 12 relative to the end of the impurity semiconductor layer 130 than being positioned on the outer side thereof. Additionally, a mutual shift between both the ends is allowed when the formula described in the first embodiment is satisfied. Thereafter, the steps illustrated in FIGS. 4B, 4C, 4E, 4F, 4H and 4I are performed, and the structures illustrated in FIGS. 7A, 7B and 7C are obtained.

### Application Embodiment

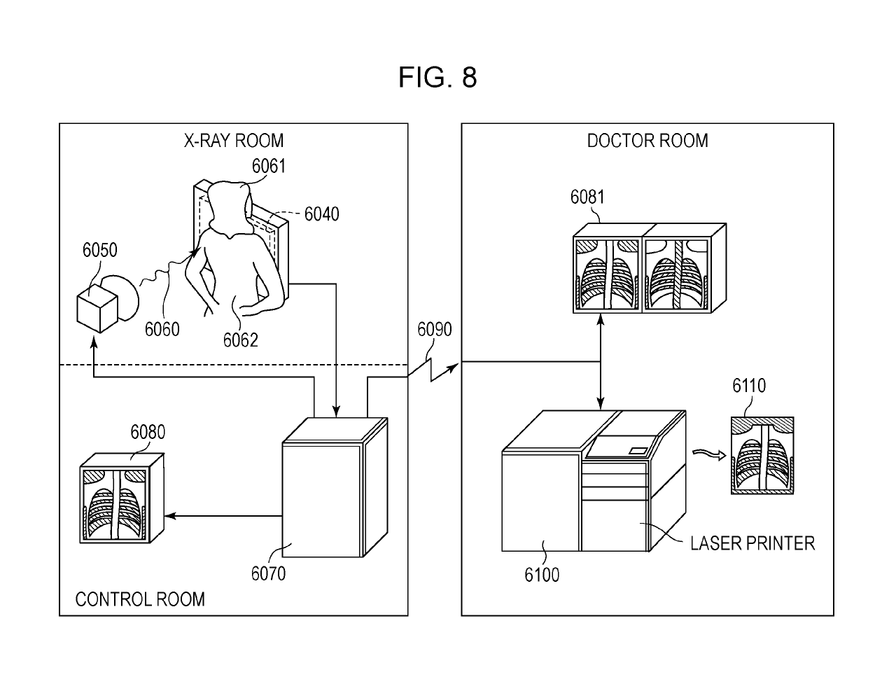

A radiation detection system using the detection device according to the embodiment of the present application will be described below with reference to FIG. 8.

An X-ray 6060 emitted from an X-ray tube 6050, i.e., a radiation source, transmits through the chest 6062 of a patient or a subject 6061 and enters individual conversion elements 12 of the conversion section 3 included in a radiation detection device 6040. The X-ray having entered the conversion elements 12 contains information regarding the interior of a body of the patient 6061. Upon the incidence of the X-ray, the radiation is converted to electric charges and electrical information is obtained in the conversion section 3. The obtained electrical information is converted to digital data and is subjected to image processing in an image processor 6070, i.e., an image processing unit, such that the information can be observed on a display 6080, i.e., a display unit, in a control room.

Furthermore, the obtained information can be transferred to a remote place via a transmission processing unit, such as a telephone line 6090, and can be displayed on a display 6081, i.e., a display unit, or stored in a storage unit, e.g., an optical disk, in a doctor room at a different location. This enables a doctor at the remote place to make a diagnosis. As an alternative, the obtained information can be recorded on a film 6110, i.e., a recording medium, by a film processor 6100, i.e., a recording unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-106883 filed May 8, 2012, which is hereby incorporated by reference herein in its entirety.

What is claimed is:

1. A method of manufacturing a detection device that includes a plurality of conversion elements disposed on a substrate, each of the conversion elements comprising a first electrode disposed on the substrate, a second electrode disposed above the first electrode, a semiconductor layer disposed between the first electrode and the second electrode, and an impurity semiconductor layer disposed between the semiconductor layer and the second electrode, the method comprising:
a film forming step of successively forming, over the plural first electrodes, a semiconductor film becoming the semiconductor layer, an impurity semiconductor film becoming the impurity semiconductor layer, and an electroconductive film becoming the second electrode, in mentioned order;
a first removing step of partly removing the electroconductive film with use of a resist formed on the electroconductive film, thereby forming an electroconductive layer on each of the plural first electrodes;
a second removing step of removing, with use of the resist, a part of the semiconductor film and a part of the impurity semiconductor film through spaces between the plural electroconductive layers by etching using an etchant having a reaction with the electroconductive film that is slower than a reaction with the impurity semiconductor film and a reaction with the semiconductor film, thereby forming the semiconductor layer and the impurity semiconductor layer on each of the plural first electrodes; and
a third removing step of removing a part of the electroconductive layer, the part being positioned on an outer side of the conversion element than an end of the impurity semiconductor layer formed in the second removing step, with use of an adjusted resist, which is obtained by removing a part of the aforesaid resist such that an end of the aforesaid resist and the end of the impurity semiconductor layer are positioned on a linear line, thereby forming the second electrode.

2. The method of manufacturing the detection device according to claim 1, wherein, in the third removing step, the second electrode is formed by removing a part of the electroconductive layer such that the end of the impurity semiconductor layer and an end of the second electrode are positioned on a linear line.

3. The method of manufacturing the detection device according to claim 1, wherein the third removing step is performed by etching a part of the electroconductive layer with use of the adjusted resist, which is obtained by removing a part of the aforesaid resist by ashing.

4. The method of manufacturing the detection device according to claim 3, wherein the detection deice includes a plurality of pixels arrayed on the substrate, each of the pixels comprising the conversion element and a thin-film transistor connected to the first electrode, and
the method further comprises the steps of:
forming a contact hole in an interlayer insulating film formed to cover the thin-film transistors, which are disposed on the substrate, at a position above each of the thin-film transistors, thereby forming a first interlayer insulating layer; and
partly removing an electroconductive film formed to cover the thin-film transistors and the first interlayer insulating layer, thereby forming the plural first electrodes.

5. The method of manufacturing the detection device according to claim 4, wherein the impurity semiconductor layer is an impurity semiconductor layer of second conductivity type, having an opposite polarity to an impurity semiconductor layer of first conductivity type disposed between the first electrode and the semiconductor layer,
the method further comprises, between the first electrode forming step and the film forming step, a step of partly removing an insulating film made of an inorganic insulating material, which is formed to cover the first interlayer insulating layer made of an organic insulating material and the first electrodes, thereby forming an insulating member such that a surface of the first interlayer insulating layer is covered with the insulating member and the first electrode, and
the second removing step is performed above the insulating member.

6. The method of manufacturing the detection device according to claim 4, wherein the conversion element further comprises an insulating layer disposed between the first electrode and the semiconductor layer,
in the film forming step, the insulating layer, the semiconductor film becoming the semiconductor layer, the impurity semiconductor film becoming the impurity semiconductor layer, and the electroconductive film becoming the second electrode are successively formed over the plural first electrodes, in mentioned order, and
in the second removing step, the semiconductor layer, the impurity semiconductor layer, and the electroconductive layer are formed on each of the plural first electrodes by removing a part of the electroconductive film, a part of the impurity semiconductor layer, and a part of the semiconductor film, while the insulating layer is left to remain.

7. The method of manufacturing the detection device according to claim 4, wherein, given that a distance between an end of the second electrode and the end of the impurity semiconductor layer is D, the distance being allowed when the second electrode is formed such that the end of the second electrode is positioned on inner side of the conversion element than the end of the impurity semiconductor layer in the third removing step, a width of the conversion element is denoted as “P”, sheet resistance of the impurity semiconductor layer is denoted as “Rs”, and on-resistance of the thin-film transistor is denoted as “Ron”, a following formula is satisfied:
4×Rs(D/P)≦Ron

8. The method of manufacturing the detection device according to claim 1, wherein the method further comprises the steps of:
forming a contact hole in an interlayer insulating film formed to cover the conversion element at a position above the second electrode, thereby forming a second interlayer insulating layer;
partly removing a transparent electroconductive oxide film formed to cover the second interlayer insulating layer and the second electrode, thereby forming a first electroconductive layer; and
partly removing a metal film formed to cover the first electroconductive layer and the second interlayer insulating layer, thereby forming a second electroconductive layer on the first electroconductive layer,
the second electroconductive layer being formed such that an orthographic projection of the second electroconductive layer is positioned between the two first electrodes adjacent to each other.

9. A detection device manufactured by the manufacturing method according to claim 1.

10. A detection system comprising:
the detection device according to claim 9;
a signal processing unit configured to process a signal from the detection device;
a display unit configured to display the signal from the signal processing unit; and
a transmission processing unit configured to transmit the signal from the signal processing unit.
